(19) United States
(12) Patent Application Publication
(10) Pub. No.: US 2024/0244936 A1
(43) Pub. Date: Jul. 18, 2024

(54) Display Having Viewing Angle Color Shift Correction

(71) Applicant: BrightView Technologies, Inc., Durham, NC (US)

(72) Inventors: Bing Shen, Cary, NC (US); Ben B. R. Smith, Durham, NC (US); Kenneth Lee Walker, Semora, NC (US); Andrew Finch, Durham, NC (US); Matthew K. Pope, Durham, NC (US)

(73) Assignee: BrightView Technologies, Inc., Durham, NC (US)

(21) Appl. No.: 18/409,717

(22) Filed: Jan. 10, 2024

Related U.S. Application Data
(60) Provisional application No. 63/479,854, filed on Jan. 13, 2023.

(51) Int. Cl. H10K 59/80

(52) U.S. Cl. CPC H10K 59/879

(57) ABSTRACT

An optical structure is described for correcting display viewing angle color shift. The optical structure includes a microlens array layer having a first surface and a second surface forming an array of microlenses. A portion of the microlens array layer is formed of a color loading material having a density that results in a desired difference between a color shift at a non-zero viewing angle and a color shift at a zero viewing angle.

### CROSS-REFERENCE TO RELATED APPLICATION

The present application claims benefit of U.S. Provisional Patent Application Ser. No. 63/479,854 filed on Jan. 13, 2023, entitled “System and Method for Display Viewing Angle Color Shift Correction”. The entire contents of U.S. Provisional Patent Application Ser. No. 63/479,854 are incorporated herein by reference.

The section headings used herein are for organizational purposes only and should not to be construed as limiting the subject matter described in the present application in any way.

### INTRODUCTION

Various lighted displays can suffer from a color shift as a function of viewing angle. For example, organic light emitting diode (OLED) displays can exhibit shifts to shorter wavelengths as viewing angle is increased as compared to direct viewing angles. As such, systems and methods to correct for viewing angle color shifts are needed. Such systems can provide displays with more uniform color with respect to viewing angles.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale; emphasis instead generally being placed upon illustrating principles of the teaching. The drawings are not intended to limit the scope of the Applicant's teaching in any way.

FIG. 1 illustrates a schematic of a known organic light emitting diode (OLED) display showing the viewing angle dependent color shift for a pixel that includes red, green, and blue subpixels.

FIG. 2A illustrates a schematic of layer structures of a known organic light emitting diode (OLED) display system with red, green, and blue subpixels.

FIG. 2B illustrates a schematic a known organic light emitting diode (OLED) top-emission subpixel.

FIG. 2C illustrates a schematic of a known organic light emitting diode (OLED) bottom-emission subpixel.

FIG. 3 illustrates a graph with measurements of color shift as a function of viewing angle for known organic light emitting diode (OLED) displays.

FIG. 4 illustrates a schematic of a known system to address the polarization properties of known organic light emitting diode (OLED) displays.

FIG. 5 illustrates an embodiment of a system for display viewing angle color shift correction of the present teaching that uses a color-loaded microlens array.

FIG. 6 illustrates an example Commission Internationale de l'Elcairage (CIE) chromaticity diagram, CIE L′,u′, v′.

FIG. 7A illustrates a system for measuring the color shift correction of different layers of embodiments of the present teaching.

FIG. 7B illustrates a graph of measured color shift as a function of viewing angle for some embodiments of microlens arrays for viewing angle color shift correction of the present teaching.

FIG. 7C illustrates a graph of measured of color shift as a function of viewing angle for some other embodiments of microlens arrays for viewing angle color shift correction of the present teaching.

### DESCRIPTION OF VARIOUS EMBODIMENTS

The present teaching will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the methods of the present teachings can be performed in any order and/or simultaneously as long as the teaching remains operable. Furthermore, it should be understood that the apparatus and methods of the present teachings can include any number or all of the described embodiments as long as the teaching remains operable.

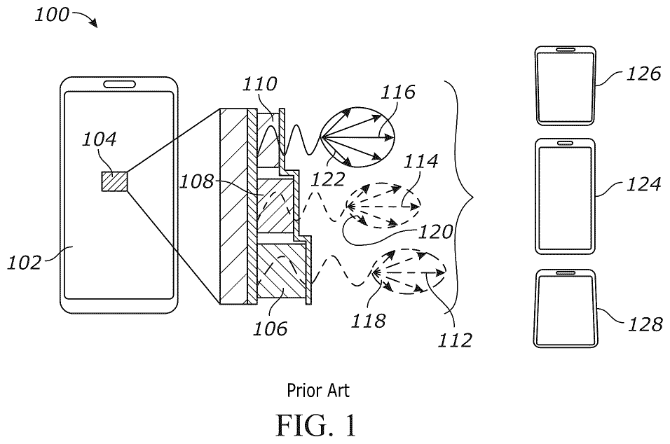

The present teaching relates to optical structures for display viewing angle color shift correction and, in particular, to optical displays having viewing angle color shift correction. FIG. 1 illustrates a schematic 100 of a known organic light emitting diode (OLED) display 102 showing the viewing angle dependent color shift for a pixel 104 that includes red 106, green 108, and blue 110 subpixels. Each subpixel 106, 108, 110 has a microcavity as a fundamental structure. The microcavity induces an optical resonance at the wavelength of emission of the pixel. As understood by those skilled in the art, the resonance wavelength of a microcavity shifts to shorter wavelengths as the viewing angle is increased. As such, on-axis light, which is indicated by arrows 112, 114, 116 will have wavelengths that are longer than off-axis axis light, which is indicated by arrows 118, 120, 122. As a result, the display viewed directly, which is shown as display orientation 124, will have a different color perceived by a viewer than the display viewed at a non-direct angle. That is, the color when looking at a viewing angle of zero with respect to the normal of the surface of the display is different than the color when looking at a non-zero viewing angle with respect to the normal to the surface of the display. This color-shift can also be described as the light source generating light with a color at a viewing angle of zero degrees relative to a normal of a surface of the light source being different than a color of light generated at a viewing angle that is non-zero with respect to the normal to the surface of the light source. It is this kind of color-shift that can be corrected using embodiments of the method and system of displays of the present teaching. The wavelength shortening of the display light occurs both for positive viewing angles, which is shown as display orientation 126, and for negative viewing angles, which is shown as display orientation 128. This color shifting can, for some light sources, also have anisotropy, for example, where the shift as a function of viewing angle is different in one dimension of the plane of the display surface than it is in a second dimension of the plane of the display surface. In addition to the cavity-induced shifting, a mismatch of red 106, green 108 and blue 110 subpixel emission profiles can also be a cause of color shift in OLED displays.

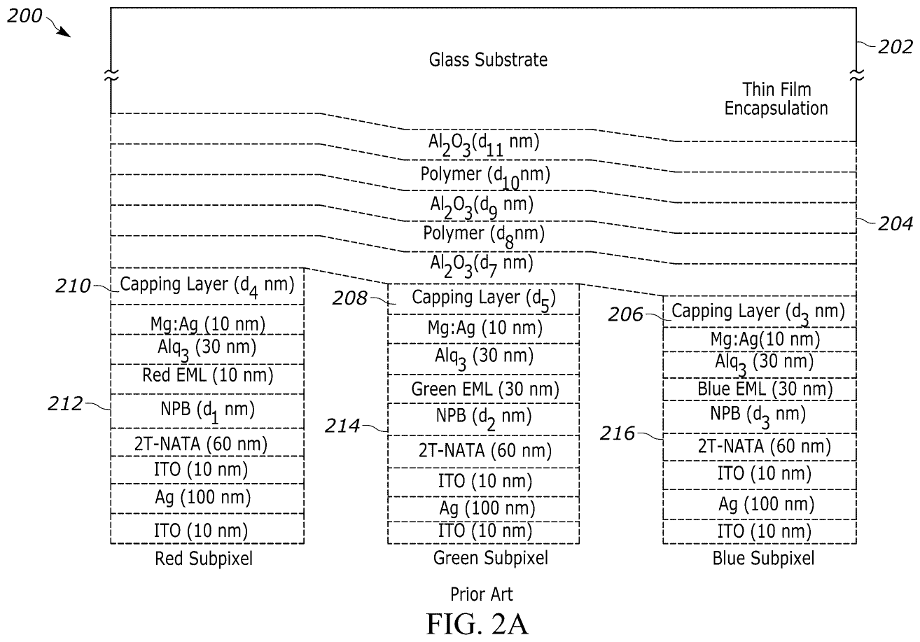

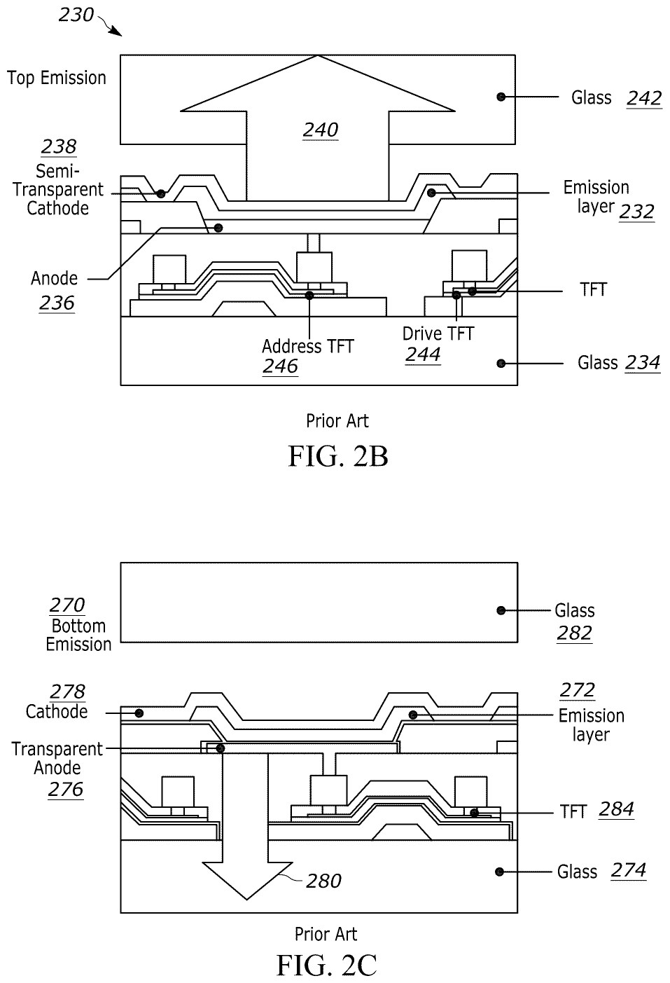

FIG. 2A illustrates a schematic of layer structures 200 of a known organic light emitting diode (OLED) display system with red, green, and blue subpixels. See, for example, Chen, H., Tan, G. and Wu, S. (2018), 74-1, entitled “Can LCDs Outperform OLED Displays in Ambient Contrast Ratio,” SID Symposium Digest of Technical Papers, 49:981-984. A top layer 202 is formed from a glass substrate that is relatively thick and supports the display. Next a thin film encapsulation layer 204 is formed that includes alternating layers of aluminum oxide and polymer material. Next a capping layers 206, 208, 210 are formed followed by layer structures for each of a red subpixel 212, green subpixel 214, and blue subpixel 216.

Various known OLED displays can operate in either top emission or bottom emission configurations. See, for example, Chen, H.W., Lee, J.H., Lin, B.Y. et al., entitled “Liquid Crystal Display and Organic Light-Emitting Diode Display: Present Status and Future Perspectives,” Light Sci. Appl. 7, 17168 (2018). FIG. 2B illustrates a schematic of a known organic light emitting diode (OLED) top-emission subpixel 230. The emission layer 232 is positioned on a glass substrate 234. An anode 236 and semi-transparent cathode 238 are formed on the bottom and top of the emission layer 232. Light 240 is emitted through an upper glass layer 242. Also shown are thin film transistors (TFT) 244, 246 used for addressing and driving the pixel.

FIG. 2C illustrates a schematic of layer structures of a known organic light emitting diode (OLED) bottom-emission subpixel 270. The emission layer 272 is positioned on a glass substrate 274. A transparent anode 276 and cathode 278 surround the emission layer 272. Light 280 is emitted through the glass substrate 274. There is an upper glass layer 282. Also shown is thin film transistor 284.

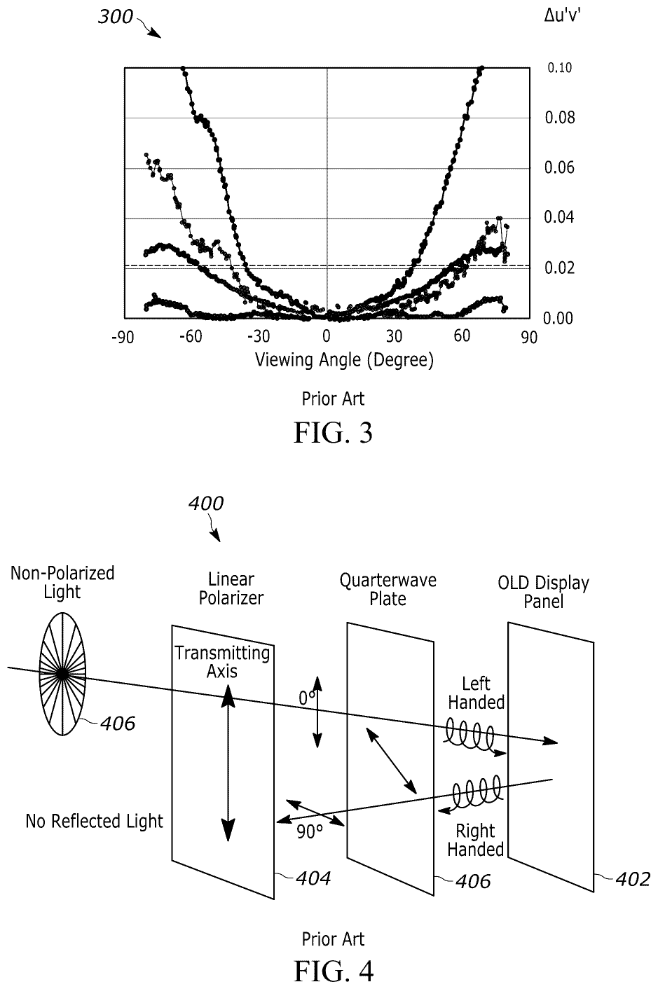

FIG. 3 illustrates a graph 300 with measurements of color shift as a function of viewing angle for known organic light emitting diode (OLED) displays. See, for example, Vieri, C., Lee, G., Balram, N., Jung, S.H., Yang, J.Y., Yoon, S.Y. and Kang, I.B. (2018), SID Symposium Digest of Technical Papers, 49:5-8. The graph 300 illustrates in separate plots the delta u′v′ as a function of viewing angle for each of a red, green, and blue pixel and also for white light from all three pixels being illuminated. This viewing angle change in color can result in limited viewing cone performance from OLED displays. The color shift behavior can be mitigated. However, it is important that the mitigation method does not substantially degrade or disturb illumination properties of the display that can reduce resolution, contrast, polarization properties and other viewing features of the display.

Known methods of reducing viewing angle dependent color shift add a diffusing agent, which is sometimes referred to as haze, in front of the display to help equalize the red, green, and blue subpixel emission profiles. The hazing technique is most effective for subpixel emission profile mismatches, but is less effective for resonance induced color shifts. The hazing technique can disturb the polarization state of emission, which has the result of increasing the display reflectance. Also, the hazing technique can degrade the ambient contrast of the display as well as degrade the display resolution (sharpness). Furthermore, the use of a diffusing agent is a limited solution because it provides control over only a single variable, which is the strength of diffusing agent. One aspect of the present teaching is that some or all of the limitations of the use of diffusing agents to mitigate viewing angle dependent color shift can be overcome by the use of microlens array layers. Another aspect of the present teaching is that the microlens array layer of the present teaching can be color loaded to achieve certain performance goals as described herein.

One feature of the present teaching is that adding microlens arrays in front of the display can mitigate viewing angle color shift in a display, including an OLED display. The microlens array causes high viewing angle light rays to travel a path length that is much longer than a path length of low viewing angle rays. As such, color shifting effects of a color loading material within the microlens array layer will have a stronger effect on the high viewing angle rays than on the lower angle rays. The larger color shift effect on the high-viewing angle rays from the microlens causes the necessary color change as a function of viewing angle to offset the viewing angle color shift in OLED displays without any color-loaded microlens array.

Embodiments of the system and method of the present teaching are effective for both cavity resonance color shift and subpixel profile mismatch color shift. In some embodiments, microlens arrays are built using material with certain desired color characteristics. For example, the material can have a blue absorbing color characteristic. As another example, the material can have a yellow loading color characteristic. Utilizing a material with certain desired color characteristics to build the microlens array is referred to as color loading. In one aspect of the present teaching color loading is applied to the microlens array.

Light traveling a distance through the microlens array, which is referred to herein as the Microlens Array (MLA) optical path, becomes a strong function of the OLED emission angle and the display viewing angle to achieve viewing angle color compensation. The methods and apparatus of the present teaching have a minimal effect on polarization state and thus, can minimizes polarization state disturbance. The methods and apparatus of the present teaching also minimizes the impact on display ambient contrast and display resolution or sharpness. The approach described herein, as compared to, for example, a diffusing agent or haze, provides an expanded design space for engineers because it is highly tunable and can be adapted to particular devices. That is, the systems and methods of display viewing angle dependent color shift correction of the present teaching are highly amenable to device-based optimization.

FIG. 4 illustrates a schematic of a known system 400 to address the polarization properties of known organic light emitting diode (OLED) displays. See, for example, Pancharatnam, S. (1956) “Generalized Theory of Interference, and its Applications, Part I. Coherent Pencils,” Proceedings of the Indian Academy of Sciences, Section A, 44 (5) pp. 247-262. See also, for example, Bong Choon Kim, Young Jin Lim, Je Hoon Song, Jun Hee Lee, Kwang-Un Jeong, Joong Hee Lee, Gi-Dong Lee, and Seung Hee Lee, “Wideband antireflective circular polarizer exhibiting a perfect dark state in organic light-emitting-diode display,” Opt. Express 22, A1725-A1730 (2014). Ambient reflections are caused by reflectivity of an OLED display panel 402 because of reflectivity in the panel. This can, for example, reduce contrast in high ambient light situations. It is desirable to reduce ambient reflections by using polarization sensitive films. For example, a linear polarizer 404 can transform incoming nonpolarized light 406 into a single type of polarization such as linear polarization. That light passes through a quarterwave plate 406, which converts the incoming linearly polarized light into a different polarization, such as, for example, left-handed circular polarization. The reflected circularly polarized light will have right-handed circular polarization, and be transformed when passing through the quarterwave plate 406 into linearly polarized light that is rotated by ninety degrees from the single linear polarization. This reflected light is, therefore, not able to pass through the linear polarizer 404, thereby reducing ambient reflection from the OLED display panel 402.

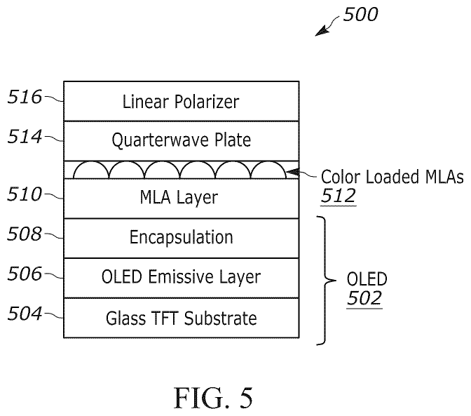

FIG. 5 illustrates an embodiment of a system 500 for display viewing angle color shift correction of the present teaching that uses a color-loaded microlens array. A layer structure is positioned over an OLED display 502. FIG. 5 illustrates a display where the light source is an OLED display 502, but the display 502 can also be other known displays having color viewing angle shift. For example, the display 502 can be made from other LEDs or other kinds of array light sources having red, green and blue pixels. The OLED display 502 can include a glass substrate and thin film transistor layer 504, an OLED emissive layer 506, and an encapsulation layer 508. For example, the OLED display 502 can include all or some of the configurations shown in FIGS. 2A-C, described herein. The OLED display 502 can also be in other known OLED display configurations. The OLED display 502 produces light such that a color of the light at a viewing angle of zero with respect to a normal of a surface of the light source is different than a color of the light at a non-zero viewing angle with respect to the normal to the surface of the light source. This light enters a microlens array layer 510 that is positioned over the display 502.

The microlens array layer 510 is positioned over the light emitting surface of the OLED display 502 to direct light that emerges from the display 502. The microlens array layer 510 includes an array of microlenses 512, which in some embodiments of the present teaching are color loaded on the surface of the microlens array layer 510 facing away from the OLED display 502. A quarterwave plate layer 514 and a linear polarizer layer 516 can be positioned over the microlens array layer 510. The microlens array layer 510 in the embodiment of the system 500 shown in FIG. 5, is shown with the color-loaded material forming the microlens structures. However, it should be understood that the color-loaded material can be positioned anywhere between the top of the OLED and the linear polarizer layer 516.

In some embodiments, the microlenses 512 with color loaded material and the microlens array layer 510 are configured to cause light at a non-zero viewing angle with respect to the normal to the surface of the OLED display 502 to travel a path length through the color loaded material of the microlenses 512 that is longer than a path length of the light through the color loaded material of the microlenses 512 at the viewing angle of zero with respect to the normal of a surface of the OLED display 502. This produces output light at the surface of display 500 that is corrected for the color of the light at the viewing angle of zero with respect to the normal of a surface of the OLED display 502, which is different than the color of the light at the non-zero viewing angle with respect to the normal to the surface of the OLED display 502.

The term “color-loaded material” as used herein refers to a material that is optically transparent so as to pass a significant amount of light at the wavelengths emitted by the OLED display 502 and that is doped or otherwise infused or modified with material that causes a color change for the transmitted light. In some embodiments, a density of doping relates to the amount of dopant in the material either by weight or volume. A higher density color loaded material will cause more color change than a lower density color loaded material.

Furthermore, a color loaded material can be described by the color it effects. For example, color loaded materials are available that affect the yellowness of light. These are referred to as blue color loaded materials. Other color loaded materials affect the blueness of the transmitted light. These are referred to as blue color loaded materials. Numerous other colors of color loaded materials exist and can be used with the displays of the present teaching. The particular ones of either or both of the material's color loading density and the material's color are used in embodiments of the present teaching to provide the desired color shift correction, which is sometimes referred to as compensation power as described further herein.

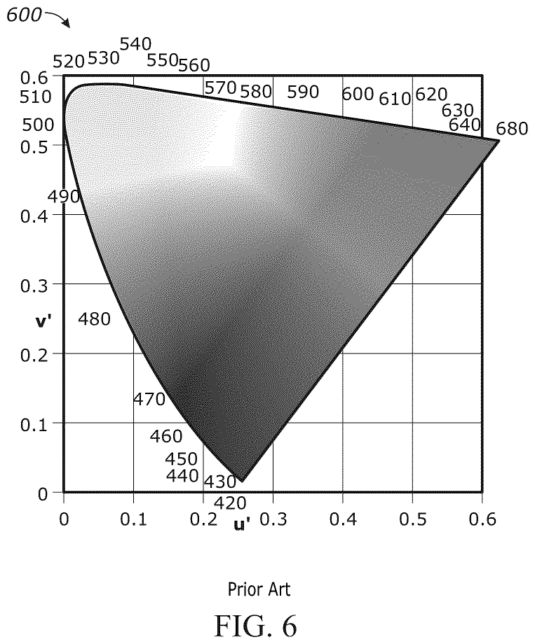

FIG. 6 illustrates an example Commission Internationale de l'Elcairage (CIE) chromaticity diagram, CIE L′,u′, v′ 600. A chromaticity diagram illustrates the hues perceivable by a standard observer of an illumination source for various pairs of color coordinates u′ and v′ that characterize the illumination wavelengths of the source. Thus, a chromaticity diagram can be used to map human color perception to values of, e.g., relative amounts of red, green, and blue luminance in a red, green, blue (RGB) display, such as an OLED display.

The observed display color shift, particularly for OLED display, is mainly between blue and yellow. As such, the change of v′ can be used as a parameter to determine color shift compensation power. Thus, the ability of a microlens array layer positioned in front of a display to mitigate color shift can be demonstrated by a measurement of delta v′, where delta v′ is the difference of the v′ of a white source at a direct viewing angle without a microlens array layer, and the v′ of the same source with the microlens array layer as a function of viewing angle. The delta v′ is measured as a function of viewing angle. Larger variation in delta v′ as function of viewing angle indicates that the layer's power to correct color shift is stronger. Thus, a stronger compensation power film exhibits larger variation of delta v′ across a range of viewing angles and a weaker compensation power film exhibits a smaller variation in delta v′ across that same range of viewing angles.

The compensation power can be changed, for example, by adjusting the percent of either blue absorbing or yellow lifting material in the microlens array. The compensation power can also be adjusted by adjusting microlens shapes. Various known microlens shapes can be used. For example, the microlens array can comprise an array of pyramid-shaped microstructures, an array of conical-shaped microstructures, an array of circular-shaped microstructures, an array of hemispherical-shaped microstructures, an array of frustrated-pyramid-shaped microstructures, and other known microstructure shapes. Furthermore, any combination of shapes can be used. The shapes can be symmetric around the particular normal to the plane of the array, or the shapes can be different in the horizontal and vertical direction of the array. The array can be a regular array, a non-regular array, or a combination of a regular array and a non-regular array. The array can have elements in various rectangular and/or circular shapes across the array. The shapes of the microstructures and the shape of the array are typically chosen to provide a desired difference in the propagation length through the material (which may or may not be a color loaded material) for incoming angles that are different. This produces a color shift of the light that passes through the microlens array. Color loaded material can compensate for color shift in light emanating from different angles from an OLED display.

It has been demonstrated experimentally by a flat colored coupon measurement that the thickness of a color compensating layer has much less color compensation effect for varying viewing angles. The compensation power can also be made anisotropic because microlens shapes could be made anisotropic. That is, the compensation power can be different in different directions in the plane of the OLED display by using a microlens shape that is different in one direction than in another direction. For example, the horizontal and vertical directions can have different compensation power as desired. This anisotropy can be caused, for example, by the color shift of the OLED display alone.

Embodiments of the color shift correction using microlens arrays that include blue absorbing or yellow lifting material can also cause a color shift on axis, or at a direct viewing angle of the display. As such, one feature of the present teaching is to use a particular percent of material to produce a desired zero-angle color shift, delta v′ at zero angle, and/or a desired rate of change of delta v′ as a function of angle.

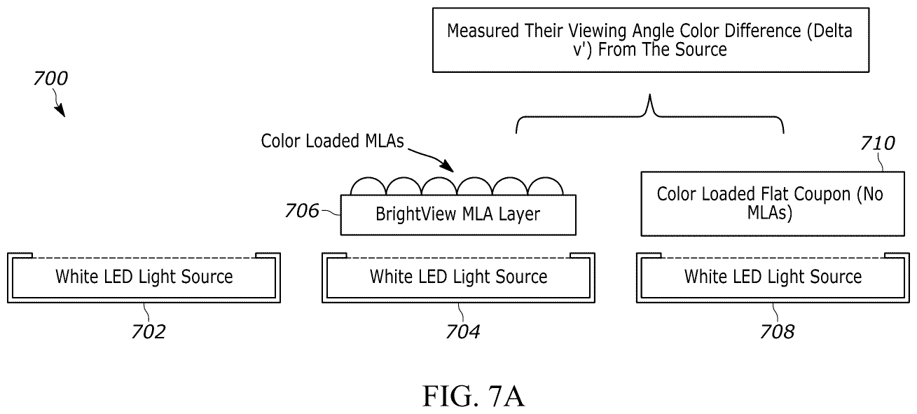

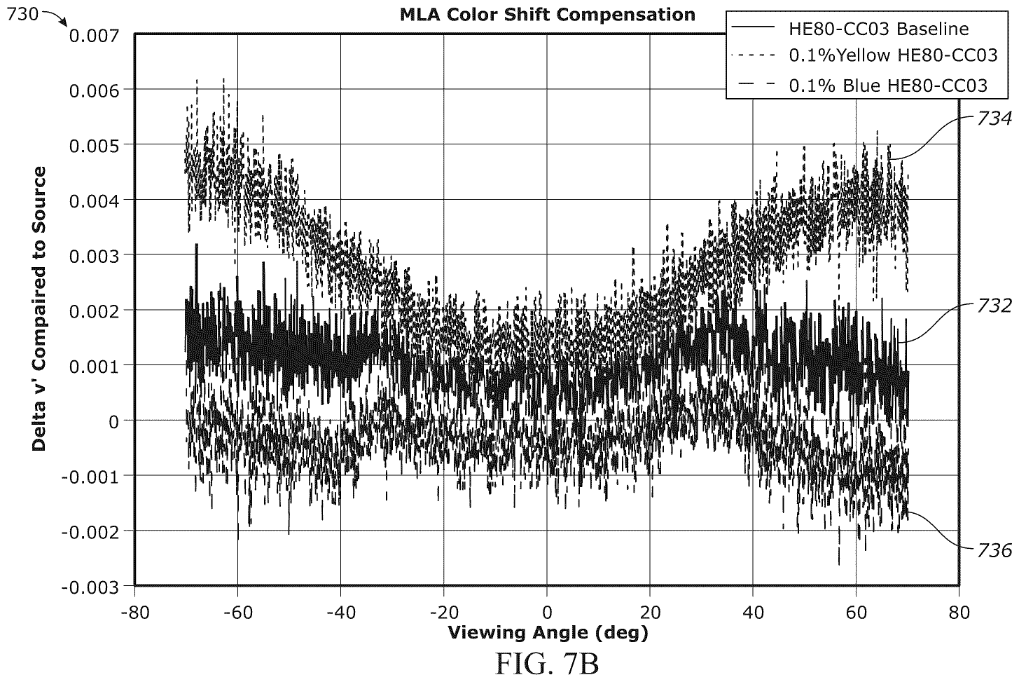

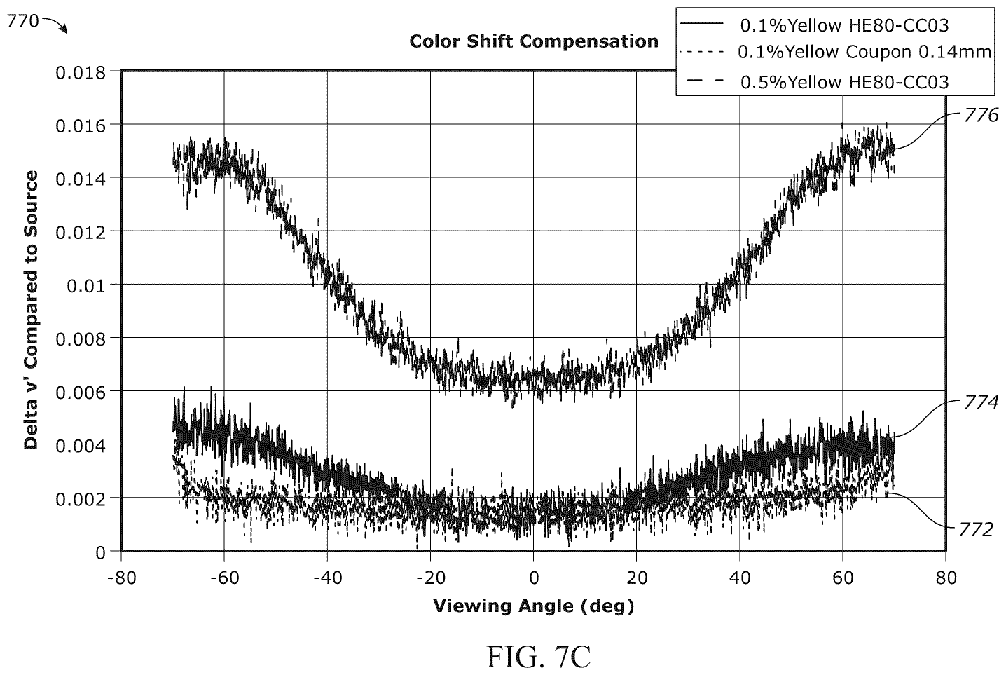

FIG. 7A illustrates a system 700 for measuring the performance of color shift correction using color-loaded microlens array layers of the present teaching. The system 700 measures color of a white LED source 702 as a function of angle. Then, the system 700 measures color as a function of angle for that same kind of white LED source 704 with a microlens array layer 706 positioned over the white LED source 704. The system 700 then determines the delta v′ for the microlens array layer 704 based on these measurements.

It is also useful to compare the color shift correction from a flat color loaded material without microlenses. As such, a white LED source 708 with a color loaded flat coupon 710 positioned over the white LED source 708 is also measured and a delta v′ is determined as a function of viewing angle for the color loaded flat coupon 710.

FIG. 7B illustrates a graph 730 of measured color shift as a function of viewing angle for some embodiments of microlens array layers for the viewing angle color shift correction of the present teaching. The graph includes plots 732, 734, 736 of delta v′ as a function of viewing angle for different correction films. The correction films are measured by finding the difference in v′ at different viewing angles of a white Lambertian source with the film and the white Lambertian source alone. The first plot 732 is for a correction film embodiment that includes a microlens array with no color material. That is, there is no color loaded material in the microlens array layer. The first plot 732 indicates a modest variation of delta v′ with viewing angle. The second plot 734 is for a correction film comprising a microlens array made from a 0.1% density yellow material. The second plot 734 indicates a much stronger variation of delta v′ with viewing angle for this case. The third plot 736 is for a correction film comprising a microlens array made from 0.1% blue material. That is, the color loaded material is 0.1% density blue. This embodiment has stronger correction than the microlens alone of the first plot 732, but not as strong as the yellow material of plot two 734. The use of the color loaded material can be used to adjust the strength of the color correction according to the present teaching. Also the direction of the delta v′ change is different for the blue color loading as compared to the yellow color loading over some range of viewing angle.

FIG. 7C illustrates a graph 770 of measured color shift as a function of viewing angle for some other embodiments of films made for viewing angle color shift correction of the present teaching. The graph 770 illustrates, for example, the effect of the microlens array on correction power, as well as the effect of the density of color material used. The first plot 772 is for a featureless layer with no microlens array, also referred to as a coupon. The layer is thicker than the color layer in the microlens arrays with color material. For example, the measured coupon layer is 0.14 mm thick. The measured color does shift because of the color-loaded coupon, as indicated by the non-zero delta v′ at zero degrees. However, there is very little variation in delta v′ as a function of viewing angle over a range from −70 degrees to +70 degrees.

The second plot 774 is for a microlens array with a yellow lifting color loading layer of 0.1% density. A more marked variation in delta v′ is shown in the plot 774, illustrating stronger correction power provided by using the microlens array. The third plot 776 is for a microlens array with a yellow lifting color loaded layer of 0.5% density. The plot 776 for the higher density color loading embodiment shows a very strong correction power over the +−70-degree viewing angle range. That is, the color shift of the microlens array layer when looking at a viewing angle of zero with respect to the normal of the surface of the display is different than the color shift when looking at a non-zero viewing angle with respect to the normal to the surface of the display. The correction power is proportional to the magnitude of the color shift difference. It is important to note that the thickness of the yellow lifting color material used in the 0.1% microlens array film and the 0.5% microlens array film is only around 30 microns. Thus, a much thinner color loaded layer is needed when the microlens structures are included on the correction layer.

One feature of the present teaching is the recognition that a color-loaded microlens array can be used to compensate for viewing angle color shift of a display. The microlens array layer enables the high viewing angle light rays to travel a path length which is much longer than the low viewing angle light rays. The compensation power is a function of microlens array structure. A color loaded flat coupon showed weak color compensation power. By using anisotropic microlens array structures, the compensation power can be engineered to be anisotropic. As just one example, a horizontal viewing cone correction can be engineered to be different from a vertical viewing cone correction. Compensation power is also a function of color loading of microlens array material. That is, the density of the color material impacts the correction power of the correction layer. The microlens array correction layer can be used together with a polarization control layer or layers to also reduce reflections from ambient light.

### Equivalents

While the Applicant's teaching is described in conjunction with various embodiments, it is not intended that the applicant's teaching be limited to such embodiments. On the contrary, the Applicant's teaching encompass various alternatives, modifications, and equivalents, as will be appreciated by those of skill in the art, which may be made therein without departing from the spirit and scope of the teaching.

What is claimed is:

1. A display comprising:
a) a light source configured to generate light with a color at a viewing angle of zero degrees relative to a normal of a surface of the light source that is different than a color of light generated at a viewing angle that is non-zero with respect to the normal to the surface of the light source;
b) a microlens array layer positioned over the light source so as to collect the generated light from the light source, the microlens array layer comprising an array of microlenses on a surface thereof; and
c) a color loaded material positioned over the light source so as to collect the generated light from the light source,
wherein the color loaded material and the microlens array layer are configured to cause the light propagating at the non-zero viewing angle with respect to the normal to the surface of the light source to travel a path length through the color loaded material that is longer than a path length through the color loaded material of the light propagating at the viewing angle of zero with respect to the normal of the surface of the light source, thereby generating light at an output of the display that is corrected for the color at the viewing angle of zero degrees relative to the normal of the surface of the light source being different than the color of light generated at the viewing angle that is non-zero with respect to the normal to the surface of the light source.

2. The display of claim 1, wherein the light source comprises an OLED array.

3. The display of claim 1, wherein the microlens array layer comprises the color loaded material.

4. The display of claim 1, wherein the array of microlenses comprises the color loaded material.

5. The display of claim 1, wherein the array of microlenses comprises an anisotropic microlens array structure in a plane of the surface of the microlens array layer.

6. The display of claim 1, wherein the color loading material comprises a blue absorbing material.

7. The display of claim 1, wherein the color loading material comprises a yellow lifting material.

8. The display of claim 1, wherein at least some microlenses in the array of microlenses are formed in a hemispherical shape, a pyramid shape, a conical shape, or a frustrated-pyramid shape.

9. The display of claim 1, further comprising a quarter waveplate positioned above the light source so as to collect the generated light from the light source.

10. The display of claim 1, further comprising a linear polarizer positioned above the light source so as to collect the generated light from the light source.

11. An optical structure for correcting display viewing angle color shift, the optical structure comprising a microlens array layer comprising a first surface and a second surface forming an array of microlenses, wherein a portion of the microlens array layer comprises a color loading material having a density that results in a desired difference between a color shift at a non-zero viewing angle and a color shift at a zero viewing angle.

12. The optical structure of claim 11, wherein the microlens array layer comprises the color loaded material.

13. The optical structure of claim 11, wherein the array of microlenses comprises the color loaded material.

14. The optical structure of claim 11, wherein the array of microlenses comprises an anisotropic microlens array structure in a plane of the microlens array layer.

15. The optical structure of claim 11, wherein the color loading material comprises a blue absorbing material.

16. The optical structure of claim 11, wherein the color loading material comprises a yellow lifting material.

17. The optical structure of claim 11, wherein the density comprises a density of nominally 0.1%.

18. The optical structure of claim 11, wherein the density comprises a density of nominally 0.5%.

19. The optical structure of claim 11, wherein at least some of the microlenses in the array of microlenses are formed in a hemispherical shape, a pyramid shape, a conical shape, or a frustrated-pyramid shape.

20. The optical structure of claim 11, further comprising a quarter waveplate positioned above the second surface of the microlens array layer so as to collect light emerging from the microlens array layer.

21. The optical structure of claim 11, further comprising a linear polarizer positioned above the second surface of the microlens array layer so as to collect light emerging from the microlens array layer.
